(19) United States
(12) Patent Application Publication
(10) Pub. No.: US 2020/0176721 A1
(43) Pub. Date: Jun. 4, 2020

(54) EVAPORATOR APPARATUS

(71) Applicant: WUHAN CHINA STAR OPTOELECTRONICS SEMICONDUCTOR DISPLAY TECHNOLOGY CO., LTD., Wuhan, Hubei (CN)

(72) Inventor: Zhao LI, Wuhan, Hubei (CN)

(21) Appl. No.: 16/462,438

(22) PCT Filed: Dec. 29, 2018
(86) PCT No.: PCT/CN2018/125200

§ 371 Date: May 20, 2019

(30) Foreign Application Priority Data
Dec. 4, 2018 (CN) 201811470696.9

(51) Int. Cl. H01L 51/56; C23C 16/448; C23C 16/455; H01L 51/00

(52) U.S. Cl. CPC H01L 51/56; H01L 51/001; C23C 16/45589; C23C 16/448

(57) ABSTRACT

The application provides an evaporator apparatus including: a base; at least one evaporator source disposed on a side surface of the base, wherein the evaporator source includes a nozzle disposed at a top of the evaporator source; more than two angle limiting boards disposed at the side surface of the base and disposed at two sides of the evaporator source, wherein a height of each of the angle limiting boards is higher than a height of the nozzle; and a moving assembly connected to the angle limiting boards; wherein each of the angle limiting boards has an opening.

### BACKGROUND OF INVENTION

### Field of Invention

The present application relates to an evaporator apparatus.

### Description of Prior Art

In recent years, organic light emitting diode (OLED) display technology has been developed by leaps and bounds. OLED products have attracted more and more attention and application due to their advantages of lightness, fast response, wide viewing angles, high contrast, and flexibility, and are mainly used in display fields such as mobile phones, tablets, and televisions. A film material of an OLED is one of the most critical technologies in OLED technology.

At present, a film of an OLED is mainly accomplished by an evaporation process. With the development of evaporation technology, an evaporation source gradually develops from a point source to a line source, and then develops into a surface source. The film formation uniformity of the point source is good, but the material utilization rate is low; the film formation uniformity of the line source is good, and the material utilization rate is high; the film formation uniformity of the surface source is good, the material utilization rate is high, but the thermal stability is poor, and structure is complicated. In comparison, line sources are favored by major OLED panel manufacturers. The line source is composed of a plurality of crucibles arranged in parallel, and a direction of evaporation of the material is controlled by an angle control plate (ACP) to control film uniformity. Since the ACP is close to an evaporation source nozzle (Nozzle), material will be accumulated on the ACP during evaporation, which may cause a risk that the evaporation source Nozzle blocks a hole. Therefore, it is necessary to design and optimize an ACP structure.

The “Description of Prior Art” section is only intended to aid for understanding the present invention, and thus the disclosure of the “Description of Prior Art” section may contain some prior art that is not known to those skilled in the art, as disclosed in the “Background” section. The content does not represent the subject matter or the problem to be solved by one or more embodiments of the present invention, nor does it mean that it is known or recognized by those skilled in the art prior to the present application.

### SUMMARY OF INVENTION

The object of the present invention is to solve the technical problems that the material in the prior art is close to the evaporation source nozzle and the material is gathered in the angle limiting plate during the evaporation process, the nozzle is blocked, and a size of the angle limiting plate is single.

The application provides an evaporator apparatus including: a base; at least one evaporator source disposed on a side surface of the base, wherein the evaporator source comprises a nozzle disposed at a top of the evaporator source; more than two angle limiting boards disposed at the side surface of the base and disposed at two sides of the evaporator source, wherein a height of each of the angle limiting boards is higher than a height of the nozzle; and a moving assembly connected to the angle limiting boards; wherein each of the angle limiting boards has an opening.

Further, the evaporator source includes a material chamber formed in the evaporator source; and a heating device attached to an outside portion of the material chamber.

Further, the moving assembly includes at least two horizontal sliding rails mounted on the base, disposed at two ends of the evaporator source, and perpendicular to the angle limiting boards and the evaporator source; and at least two vertical sliding rails disposed with the angle limiting boards in parallel arrangement, wherein bottom ends of the vertical sliding rails are slidably connected to the horizontal sliding rails; wherein the ends of the angle limiting boards are slidably connected to the vertical sliding rails.

Further, a height of a bottom edge of the opening is lower than a height of the nozzle; a height of a top edge of the opening is higher than the height of the nozzle.

Further, a height of the angle limiting board is 50 mm-100 mm.

Further, a length of the angle limiting board is 500 mm-1000 mm.

Further, a height of the opening is 0-60 mm.

Further, a distance defined between a left edge of the opening and a left side of the angle limiting board is 0-60 mm; a distance defined between a right edge of the opening and a right side of the angle limiting board is 0-60 mm.

Further, a distance defined between the opening and a bottom end of the angle limiting board is 5 mm-15 mm.

Further, a shape of the opening comprises one selected from a group consisting of a rectangle, a rounded rectangle, an oval, and a trapezoid.

The beneficial effect of this invention is: the angle limiting board with a central opening is used for limiting the evaporation angle and is used for reducing the aggregate growth of the material on the angle limiting plate to reduce the risk of plugging holes of the evaporation source nozzle; meanwhile, the angle limiting plates with different shapes and sizes can meet the needs of different evaporation materials, different evaporation processes, and different evaporation chamber configurations.

### BRIEF DESCRIPTION OF DRAWINGS

FIG. 1 is a structural view of an evaporator apparatus of a first, a second, or a third exemplary embodiment of the present disclosure.

FIG. 2 is a front view of an angle limiting board of the first, the second, or the third exemplary embodiment of the present disclosure.

FIG. 3 is a space diagram of the angle limiting board of the first, the second, or the third exemplary embodiment of the present disclosure.

FIG. 4 is a front view of the angle limiting board of the first exemplary embodiment of the present disclosure.

FIG. 5 is a front view of another angle limiting board of the first exemplary embodiment of the present disclosure.

FIG. 6 is a front view of the angle limiting board of the second exemplary embodiment of the present disclosure.

FIG. 7 is a front view of another angle limiting board of the second exemplary embodiment of the present disclosure.

FIG. 8 is a front view of the angle limiting board of the third exemplary embodiment of the present disclosure.

FIG. 9 is a front view of another angle limiting board of the third exemplary embodiment of the present disclosure.

Components are identified as follows:
1, angle limiting board; 11, opening;
2, evaporator source; 21, nozzle;
3, moving assembly; 31, horizontal sliding rail; 32, vertical sliding rail;
4, base.

### DETAILED DESCRIPTION OF PREFERRED EMBODIMENTS

### Best Mode

The preferred embodiments of the present invention are described in detail below with reference to the accompanying drawings, in which FIG. Those skilled in the art will more readily understand how to implement the invention. The present invention may, however, be embodied in many different forms and embodiments, and the scope of the invention is not limited to the embodiments described herein.

The directional terms mentioned in the present invention, such as “upper”, “lower”, “before”, “after”, “left”, “right”, “inside”, “outside”, “side”, etc., are only attached The directional terms used in the drawings are used to explain and explain the invention, and are not intended to limit the scope of the invention.

In the drawings, structurally identical components are denoted by the same reference numerals, and structural or functionally similar components are denoted by like reference numerals. Moreover, the size and thickness of each component shown in the drawings are arbitrarily shown for ease of understanding and description, and the invention does not limit the size and thickness of each component.

When a component is described as “on” another component, the component can be placed directly on the other component; there can also be an intermediate component that is placed on the intermediate component And the intermediate component is placed on another component.

### Embodiment I

Referring to FIG. 1, an evaporator apparatus is provided and includes a base 4, evaporator sources 2, angle limiting boards 1, and a moving assembly 3.

The evaporator source 2 is disposed on the base 4, a material chamber (not shown) is formed in the evaporator source 2 and is configured for containing evaporator materials. A heating device (not shown) is attached to an outside portion of the material chamber and is configured for heating the evaporator materials contained in the material chamber. A nozzle 21 is disposed at a top of the evaporator source 2 and is configured for spraying the evaporator materials to an upper substrate (not shown).

The angle limiting boards 1 are disposed upon the base 4 and placed at both sides of the evaporator source 2, and a height of each of the angle limiting boards is higher than a height of the nozzle 21 to limit a spraying range of the spraying materials sprayed by the nozzle 21. The evaporator sources 2 and the angle limiting boards 1 are set in an alternated manner, that is, each of the evaporator sources 2 is sandwiched between two adjacent angle limiting boards 1.

The moving assembly 3 includes horizontal sliding rails 31 and vertical sliding rails 32. The horizontal sliding rails 31 are mounted on the base 4, disposed at two ends of the evaporator source 2, and perpendicular to the angle limiting boards 1 and the evaporator source 2. The vertical sliding rails 32 are disposed with the angle limiting boards 1 in parallel arrangement, bottom ends of the vertical sliding rails 32 are sliding connected to the horizontal sliding rails 31 to make the vertical sliding rails 32 slide along the horizontal sliding rails 31. The angle limiting boards 1 are sliding connected to vertical sliding rails 32 to make the angle limiting boards 1 slide up and down and to adjust a height of the angle limiting boards 1. The angle limiting boards 1 can move between two adjacent evaporator sources 2 via the moving assembly 3 to adjust distances between the angle limiting boards 1 and the evaporator sources 2 and a height of the angle limiting boards 1, thereby controlling a shielding area of the spraying materials.

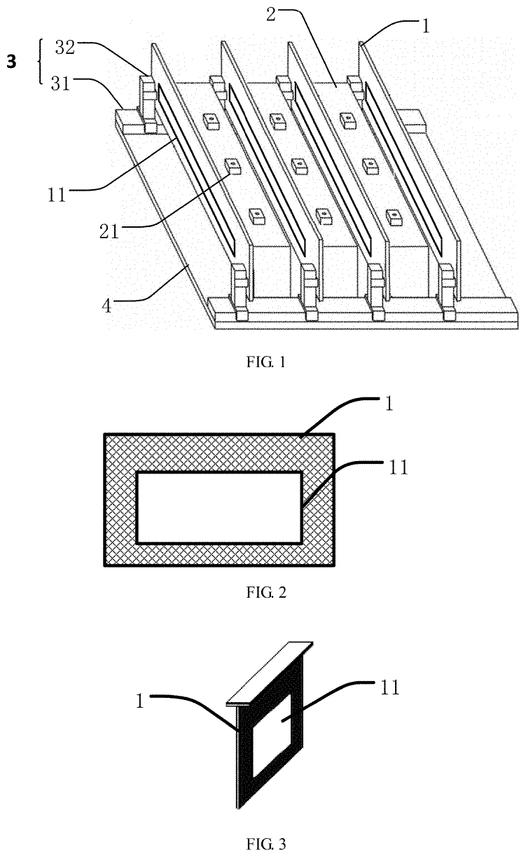

Referring to FIGS. 2 and 3, an opening 11 is defined at a center of the angle limiting boards 1, a length of the angle limiting board 1 is 500 mm-1000 mm, a height of the angle limiting board 1 is 50 mm-100 mm, a distance defined between the opening 11 and a bottom end of the angle limiting board 1 is 5 mm-15 mm. In this embodiment, the length of the angle limiting board 1 is 560 mm, the height of angle limiting board 1 is 70 mm, the distance defined between the opening 11 and the bottom end of the angle limiting board 1 is 10 mm, a size and shape of the opening 11 is not limiting. A height of the opening 11 is 0-60 mm, a distance defined between a left edge of the opening 11 and a left side of the angle limiting board 1 is 0-60 mm; a distance defined between a right edge of the opening 11 and a right side of the angle limiting board 1 is 0-60 mm.

The nozzle 21 can be a linear nozzle 21, and the nozzle 24 includes a plurality of ejection holes distributed in an in-line shape, the ejection holes are arranged in a direction perpendicular to a moving direction of the substrate. An angle is defined by two lines defined between the ejection hole and two angle limiting boards 1 disposed two sides of the ejection hole, a degree of the angle is defined as a degree of an angle of the spray materials sprayed by the nozzle 21. A distance defined between the base and the nozzle 21 determines an area of the spray materials deposing on a surface of the base sprayed by the nozzle 21. In order to adapt to different deposition requirements of the substrate, it is necessary to change the area of the material deposing on the surface of the base sprayed by the nozzle 21, the angle limiting plate 1 is used to block part of the material sprayed by the nozzle 21 to control a range of the material deposing on the surface of the base sprayed by the nozzle 21. A central opening is used for limiting the aggregate growth of the material on the angle limiting plate to reduce the risk of plugging holes of the evaporation source nozzle.

Referring to FIG. 4, a height of the opening 11 is 20 mm and a distance from the bottom of the angle limiting plate 1 is 10 mm, a distance defined between a left edge of the opening 11 and a left side of the angle limiting board 1 is 30 mm, a distance defined between a right edge of the opening 11 and a right side of the angle limiting board 1 is 30 mm, a shape of the opening 11 is a rectangle.

Referring to FIG. 5, a height of the opening 11 is 20 mm and a distance from the bottom of the angle limiting plate 1 is 10 mm, a distance defined between a left edge of the opening 11 and a left side of the angle limiting board 1 is 30 mm, a distance defined between a right edge of the opening 11 and a right side of the angle limiting board 1 is 30 mm, a shape of the opening 11 is a rounded rectangle. A shape of the opening 11 can be other shapes such as an ellipse in addition to the rectangle and rounded rectangle provided in the embodiment.

By changing the original angle limiting plate to a central opening structure, while ensuring a limitation of an evaporation angle, the accumulation growth of the material on the angle limiting plate can be reduced, thereby reducing the risk of the evaporation source nozzle being blocked; different sizes and shapes of the opening can meet the needs of different evaporation materials, different evaporation processes, and different evaporation chamber structures.

### Embodiment Mode

Referring to FIG. 1, an evaporator apparatus is provided and includes a base 4, evaporator sources 2, angle limiting boards 1, and a moving assembly 3.

The evaporator source 2 is disposed on the base 4, a material chamber (not shown) is formed in the evaporator source 2 and is configured for containing evaporator materials. A heating device (not shown) is attached to an outside portion of the material chamber and is configured for heating the evaporator materials contained in the material chamber. A nozzle 21 is disposed at a top of the evaporator source 2 and is configured for spraying the evaporator materials to an upper substrate (not shown).

The angle limiting boards 1 are disposed upon the base 4 and placed at both sides of the evaporator source 2, and a height of each of the angle limiting boards is higher than a height of the nozzle 21 to limit a spraying range of the spraying materials sprayed by the nozzle 21. The evaporator sources 2 and the angle limiting boards 1 are set in an alternated manner, that is, each of the evaporator sources 2 is sandwiched between two adjacent angle limiting boards 1.

The moving assembly 3 includes horizontal sliding rails 31 and vertical sliding rails 32. The horizontal sliding rails 31 are mounted on the base 4, disposed at two ends of the evaporator source 2, and perpendicular to the angle limiting boards 1 and the evaporator source 2. The vertical sliding rails 32 are disposed with the angle limiting boards 1 in parallel arrangement, bottom ends of the vertical sliding rails 32 are sliding connected to the horizontal sliding rails 31 to make the vertical sliding rails 32 slide along the horizontal sliding rails 31. The angle limiting boards 1 are sliding connected to vertical sliding rails 32 to make the angle limiting boards 1 slide up and down and to adjust a height of the angle limiting boards 1. The angle limiting boards 1 can move between two adjacent evaporator sources 2 via the moving assembly 3 to adjust distances between the angle limiting boards 1 and the evaporator sources 2 and a height of the angle limiting boards 1, thereby controlling a shielding area of the spraying materials.

Referring to FIGS. 2 and 3, an opening 11 is defined at a center of the angle limiting boards 1, a length of the angle limiting board 1 is 500 mm-1000 mm, a height of the angle limiting board 1 is 50 mm-100 mm, a distance defined between the opening 11 and a bottom end of the angle limiting board 1 is 5 mm-15 mm. In this embodiment, the length of the angle limiting board 1 is 560 mm, the height of angle limiting board 1 is 70 mm, the distance defined between the opening 11 and the bottom end of the angle limiting board 1 is 10 mm, a size and shape of the opening 11 is not limiting. A height of the opening 11 is 0-60 mm, a distance defined between a left edge of the opening 11 and a left side of the angle limiting board 1 is 0-60 mm; a distance defined between a right edge of the opening 11 and a right side of the angle limiting board 1 is 0-60 mm.

The nozzle 21 can be a linear nozzle 21, and the nozzle 21 includes a plurality of ejection holes distributed in an in-line shape, the ejection holes are arranged in a direction perpendicular to a moving direction of the substrate. An angle is defined by two lines defined between the ejection hole and two angle limiting boards 1 disposed two sides of the ejection hole, a degree of the angle is defined as a degree of an angle of the spray materials sprayed by the nozzle 21. A distance defined between the base and the nozzle 21 determines an area of the spray materials deposing on a surface of the base sprayed by the nozzle 21. In order to adapt to different deposition requirements of the substrate, it is necessary to change the area of the material deposing on the surface of the base sprayed by the nozzle 21, the angle limiting plate 1 is used to block part of the material sprayed by the nozzle 21 to control a range of the material deposing on the surface of the base sprayed by the nozzle 21. A central opening is used for limiting the aggregate growth of the material on the angle limiting plate to reduce the risk of plugging holes of the evaporation source nozzle.

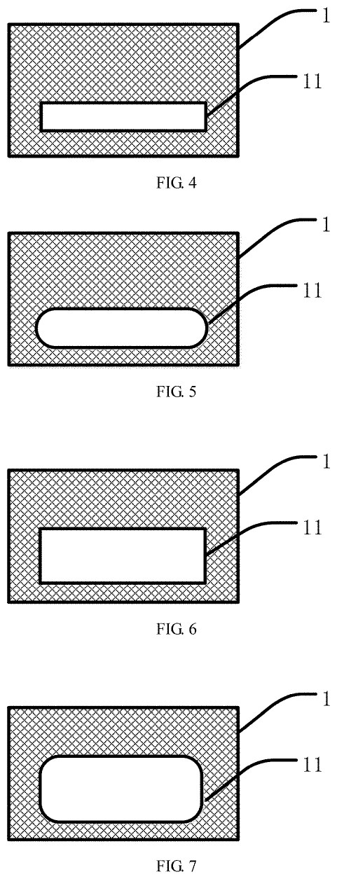

Referring to FIG. 6, a height of an opening 11 is 35 mm and a distance from a bottom of an angle limiting plate 1 is 10 mm, a distance defined between a left edge of the opening 11 and a left side of the angle limiting board 1 is 35 mm, a distance defined between a right edge of the opening 11 and a right side of the angle limiting board 1 is 35 mm, a shape of the opening 11 is a rectangle.

Referring to FIG. 7, a height of the opening 11 is 35 mm and a distance from the bottom of the angle limiting plate 1 is 10 mm, a distance defined between a left edge of the opening 11 and a left side of the angle limiting board 1 is 35 mm, a distance defined between a right edge of the opening 11 and a right side of the angle limiting board 1 is 35 mm, a shape of the opening 11 is a rounded rectangle. A shape of the opening 11 can be other shapes such as an ellipse in addition to the rectangle and rounded rectangle provided in the embodiment.

By changing the original angle limiting plate to a central opening structure, while ensuring a limitation of an evaporation angle, the accumulation growth of the material on the angle limiting plate can be reduced, thereby reducing the risk of the evaporation source nozzle being blocked; different sizes and shapes of the opening can meet the needs of different evaporation materials, different evaporation processes, and different evaporation chamber structures.

### Embodiment 3

Referring to FIG. 1, an evaporator apparatus is provided and includes a base 4, evaporator sources 2, angle limiting boards 1, and a moving assembly 3.

The evaporator source 2 is disposed on the base 4, a material chamber (not shown) is formed in the evaporator source 2 and is configured for containing evaporator materials. A heating device (not shown) is attached to an outside portion of the material chamber and is configured for heating the evaporator materials contained in the material chamber. A nozzle 21 is disposed at a top of the evaporator source 2 and is configured for spraying the evaporator materials to an upper substrate (not shown).

The angle limiting boards 1 are disposed upon the base 4 and placed at both sides of the evaporator source 2, and a height of each of the angle limiting boards is higher than a height of the nozzle 21 to limit a spraying range of the spraying materials sprayed by the nozzle 21. The evaporator sources 2 and the angle limiting boards 1 are set in an alternated manner, that is, each of the evaporator sources 2 is sandwiched between two adjacent angle limiting boards 1.

The moving assembly 3 includes horizontal sliding rails 31 and vertical sliding rails 32. The horizontal sliding rails 31 are mounted on the base 4, disposed at two ends of the evaporator source 2, and perpendicular to the angle limiting boards 1 and the evaporator source 2. The vertical sliding rails 32 are disposed with the angle limiting boards 1 in parallel arrangement, bottom ends of the vertical sliding rails 32 are sliding connected to the horizontal sliding rails 31 to make the vertical sliding rails 32 slide along the horizontal sliding rails 31. The angle limiting boards 1 are sliding connected to vertical sliding rails 32 to make the angle limiting boards 1 slide up and down and to adjust a height of the angle limiting boards 1. The angle limiting boards 1 can move between two adjacent evaporator sources 2 via the moving assembly 3 to adjust distances between the angle limiting boards 1 and the evaporator sources 2 and a height of the angle limiting boards 1, thereby controlling a shielding area of the spraying materials.

Referring to FIGS. 2 and 3, an opening 11 is defined at a center of the angle limiting boards 1, a length of the angle limiting board 1 is 500 mm-1000 mm, a height of the angle limiting board 1 is 50 mm-100 mm, a distance defined between the opening 11 and a bottom end of the angle limiting board 1 is 5 mm-15 mm. In this embodiment, the length of the angle limiting board 1 is 560 mm, the height of angle limiting board 1 is 70 mm, the distance defined between the opening 11 and the bottom end of the angle limiting board 1 is 10 mm, a size and shape of the opening 11 is not limiting. A height of the opening 11 is 0-60 min, a distance defined between a left edge of the opening 11 and a left side of the angle limiting board 1 is 0-60 mm; distance defined between a right edge of the opening 11 and a right side of the angle limiting board 1 is 0-60 mm.

The nozzle 21 can be a linear nozzle 21, and the nozzle 21 includes a plurality of ejection holes distributed in an in-line shape, the ejection holes are arranged in a direction perpendicular to a moving direction of the substrate. An angle is defined by two lines defined between the ejection hole and two angle limiting boards 1 disposed two sides of the ejection hole, a degree of the angle is defined as a degree of an angle of the spray materials sprayed by the nozzle 21. A distance defined between the base and the nozzle 21 determines an area of the spray materials deposing on a surface of the base sprayed by the nozzle 21. In order to adapt to different deposition requirements of the substrate, it is necessary to change the area of the material deposing on the surface of the base sprayed by the nozzle 21, the angle limiting plate 1 is used to block part of the material sprayed by the nozzle 21 to control a range of the material deposing on the surface of the base sprayed by the nozzle 21. A central opening is used for limiting the aggregate growth of the material on the angle limiting plate to reduce the risk of plugging holes of the evaporation source nozzle.

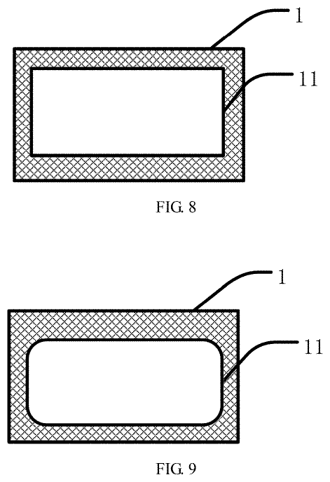

Referring to FIG. 8, a height of an opening 11 is 50 mm and a distance from a bottom of an angle limiting plate 1 is 10 mm, a distance defined between a left edge of the opening 11 and a left side of the angle limiting board 1 is 20 mm, a distance defined between a right edge of the opening 11 and a right side of the angle limiting board 1 is 20 mm, a shape of the opening 11 is a rectangle.

Referring to FIG. 9, a height of the opening 11 is 50 mm and a distance from a bottom of an angle limiting plate 1 is 10 mm, a distance defined between a left edge of the opening 11 and a left side of the angle limiting board 1 is 20 mm, a distance defined between a right edge of the opening 11 and a right side of the angle limiting board 1 is 20 mm, a shape of the opening 11 is a rounded rectangle. A shape of the opening 11 can be other shapes such as an ellipse in addition to the rectangle and rounded rectangle provided in the embodiment.

By changing the original angle limiting plate to a central opening structure, while ensuring a limitation of an evaporation angle, the accumulation growth of the material on the angle limiting plate can be reduced, thereby reducing the risk of the evaporation source nozzle being blocked; different sizes and shapes of the opening can meet the needs of different evaporation materials, different evaporation processes, and different evaporation chamber structures.

The description made above is only the embodiment of the present application. It is noted that those with ordinary skill in the technique field could make various modifications and polishes within the theory of the present application, and these modifications and polishes should be deemed as the protection scope of the present application.

What is claimed is:

1. An evaporator apparatus, comprising:
a base;
at least one evaporator source disposed on a side surface of the base, wherein the evaporator source comprises a nozzle disposed at a top of the evaporator source;
more than two angle limiting boards disposed at the side surface of the base and disposed at two sides of the evaporator source, wherein a height of each of the angle limiting boards is higher than a height of the nozzle; and
a moving assembly connected to the angle limiting boards;
wherein each of the angle limiting boards has an opening.

2. The evaporator apparatus of claim 1, wherein the evaporator source comprises:
a material chamber formed in the evaporator source; and
a heating device attached to an outside portion of the material chamber.

3. The evaporator apparatus of claim 1, wherein the moving assembly comprises:
at least two horizontal sliding rails mounted on the base, disposed at two ends of the evaporator source, and perpendicular to the angle limiting boards and the evaporator source; and
at least two vertical sliding rails disposed with the angle limiting boards in parallel arrangement, wherein bottom ends of the vertical sliding rails are sliding connected to the horizontal sliding rails;
wherein ends of the angle limiting boards are sliding connected to the vertical sliding rails.

4. The evaporator apparatus of claim 1, wherein a height of a bottom edge of the opening is lower than a height of the nozzle; and/or
a height of a top edge of the opening is higher than the height of the nozzle.

5. The evaporator apparatus of claim 1, wherein a height of the angle limiting board is 50 mm-100 mm.

6. The evaporator apparatus of claim 1, wherein a length of the angle limiting board is 500 mm-1000 mm.

7. The evaporator apparatus of claim 1, wherein a height of the opening is 0-60 mm.

8. The evaporator apparatus of claim 1, wherein a distance defined between a left edge of the opening and a left side of the angle limiting board is 0-60 mm; a distance defined between a right edge of the opening and a right side of the angle limiting board is 0-60 mm.

9. The evaporator apparatus of claim 1, wherein a distance defined between the opening and a bottom end of the angle limiting board is 5 mm-15 mm.

10. The evaporator apparatus of claim 1, wherein a shape of the opening comprises one selected from a group consisting of a rectangle, a rounded rectangle, an oval, and a trapezoid.
